(19) United States
(12) Patent Application Publication
(10) Pub. No.: US 2004/0071970 A1
(43) Pub. Date: Apr. 15, 2004

(54) Device housing having a shielding gasket or wall comprising a conductive coating

(76) Inventors: Helmut Kahl, Berlin (DE); Bernd Tiburtius, Kleinmachnow (DE)

Correspondence Address: Patrick W. Rasche, Armstrong Teasdale LLP, Suite 2600, One Metropolitan, Sq., St Louis, MO, 63102, US

(21) Appl. No.: 10/386,368

(22) Filed: Mar. 11, 2003

(30) Foreign Application Priority Data
Mar. 11, 2002 (DE) 102 10 577.4

(51) Int. Cl. C23C 14/00

(52) U.S. Cl. 428/411.1; 204/192.15

(57) ABSTRACT

Device housing with a shielding gasket or wall that has a conductive coating, said conductive coating being formed as a thin layer of tin or a tin alloy.

### DESCRIPTION

The invention relates to a housing that is designed to enclose an electronic device and has at least one shielding gasket or wall with a conductive coating; equipment of this kind is produced and employed in large numbers to serve, for example, as a telecommunications (in particular mobile telephone) terminal.

In order to produce the electromagnetic shielding that such equipment requires, various techniques are known, of which the one that has recently become especially widely used is the so-called dispensing procedure, i.e. using a computer-controlled dispensing needle or nozzle to apply to a substrate a pasty sealing material, and then allowing it to harden. Alternative shielding gaskets are known that have been formed by placing a form tool onto an appropriate part of the housing and injecting the liquid or pasty sealant into the form tool (normally at an elevated temperature). Sealing means are also known that have been prefabricated as continuous (extruded) profiles, which are attached in particular to the outer edges of a housing and specifically by insertion into grooves provided there for the purpose.

Similarly, various techniques have been developed to provide the gaskets of interest here with the conductivity required to produce the desired EMI-shielding effect. An especially common one is to mix small particles of electrically conductive material (in particular metal, but also carbon or the like) into the liquid or pasty mass of sealant material, in proportions such as to ensure an adequate volume conductivity of the material. A disadvantage of this procedure is that it consumes a relatively large amount of conductive material and necessitates a compromise between a large proportion of filler, to achieve advantageous EMI-shielding properties, and a minimal impairment of the elasticity and/or compressibilty parameters of the base material. Furthermore, there are sedimentation problems that could restrict the extent to which shielding materials filled in this way can be used for certain applications.

Another alternative approach is to construct a gasket from pure sealing material and subsequently apply a conductive coating. This coating can be applied in the form of an added layer of sealing material filled with a conductive substance as described above—forming an elastomeric covering layer—or as a purely metallic thin layer. The various embodiments of this method are also encumbered with certain disadvantages: in the housing of the first variant, the shielding effect is limited in principle, and a coating according to the second variant is susceptible to corrosion and mechanical damage.

The objective of the invention is to disclose a device housing that is technologically simple and economical to manufacture, while satisfying the existing requirements for electromagnetic insulation or compatibility.

This objective is achieved with respect to a first aspect of the invention by a device housing with the characteristics given in Claim 1, and with respect to a second, relatively independent aspect of the invention by device housings with the characteristics given in Claim 7 or 8. The subordinate claims refer to advantageous concrete implementations of the invention.

The solution presented here with regard to the first aspect is a device housing in which the EMI shielding is extremely stable even under highly stressful environmental conditions, for example during use outdoors, in a chemically aggressive atmosphere or during frequent opening and closing of the housing. Furthermore, the shielding gasket is economical and technically simple to manufacture, which contributes to reducing the cost of the equipment as a whole.

In an advantageous embodiment of the invention in this sense the tin alloy employed is a Sn/Pb alloy with low Pb content, in particular less than 5% Pb by mass. Such a composition differs from the tin compounds ordinarily used for soldering in that both its conductivity and its mechanical and serviceability characteristics make it particularly suitable for EMI shielding.

In a somewhat more complicated embodiment, but one that has particularly good shielding properties, the conductive coating is constructed in two layers: a basal layer made of a highly conductive metal, in particular copper or a copper alloy, is covered by a thin layer of tin or the tin alloy. Here the highly conductive basal layer advantageously endows the shielding gasket with a low surface resistance, whereas the covering layer provides its advantageous chemical and mechanical properties.

In another preferred embodiment the conductive coating has a total thickness in the range between 0.5 μm and 10 μm. Although greater layer thicknesses can also be useful for special applications, this thickness range allows the EMI properties required for standard applications to be achieved with a relatively small amount of material and correspondingly low costs.

Another useful embodiment of the invention provides for the shielding gasket or wall to be formed by an elastomer applied to a substrate by means of a dispenser. This enables advantageous handling, in particular of shielding gaskets with small cross sections for miniaturized electronic devices, while simultaneously preserving very good mechanical stability of the gasket structure.

The substrate will often be part of the device housing and thus, in order to form a closed shielding cage, will itself be made of metal or have a metallic coating, and the conductive surface of the shielding gasket will be in contact with another part of the housing, which customarily likewise has a shielding action. However, it is also possible for the substrate—or else the opposite part of the device, the surface of which makes contact with the shielding gasket—to be a component carrier (in particular a printed circuit board).

If the housing comprises a “shielding wall” coated in accordance with the solution proposed here, this wall advantageously consists of several beads of the elastomer stacked one on top of another, or a single, tall elastomer bead, the height of which is at least twice its width. Such shielding walls exhibit the advantages cited above for shielding gaskets applied from a dispenser. Furthermore, the method of subdividing the interior of a device housing by shielding walls constructed in this way makes possible simple and rapid structural alterations, because an altered housing structure can be achieved without changing the tools, substantially entirely by reprogramming a known dispensing installation and the apparatus used to apply the proposed conductive coating.

According to a relatively independent aspect of the invention, the shielding gasket or wall consists substantially of a thermoplastic or duroplastic polymer. The mechanical properties of such polymers can be adjusted by suitable additives (softeners, etc.) so that their elasticity and/or compressibility are as required to produce a mechanical sealing action in the particular structure concerned, so that these polymers are well suited for use as substrates for the proposed shielding coating.

Special technological advantges are obtained when in a preferred embodiment the shielding gasket or wall is injection molded, in particular so that its material is continuous with that of the substrate. That is, by this means separate processing steps to produce the basic profiles of the shielding gaskets or walls can be eliminated, which further reduces the cost of manufacturing the housing.

Insofar as necessary, the shielding actions of the shielding gasket or walls for devices of the kind proposed above can be further improved by providing the material of which the shielding gasket or wall is made with an electrically conductive filling, in particular comprising conductive metal and/or carbon particles—although this measure increases the amount of conductive material that must be used and raises the costs correspondingly.

The proposed conductive coating with tin or a tin alloy can be produced with established vacuum-coating methods, in particular as a vapor-deposited or sputtered layer, to enable mass production with high and uniform quality. An alternative possibility is to produce it as a “classical” sprayed-on coating (under atmospheric pressure). Finally, it is also possible to employ other coating methods that have become established for metallic or metal-containing layers, such as galvanic or dipping methods.

Devices of the kind concerned here include, in particular, mobile wireless terminals or other telecommunications terminals or components of mobile wireless networks (in particular base stations) that constitute a source of EMI or are vulnerable to such interference, as well as EMI-sensitive data communication or data processing devices and parts thereof. Other devices of this kind are employed in the areas of sensing systems, operational measurement and process-control technology, radio navigation and the like.

Additional advantages and useful features of the invention will be evident from the following description, in brief outline, of preferred exemplary embodiments and aspects with reference to figures, wherein

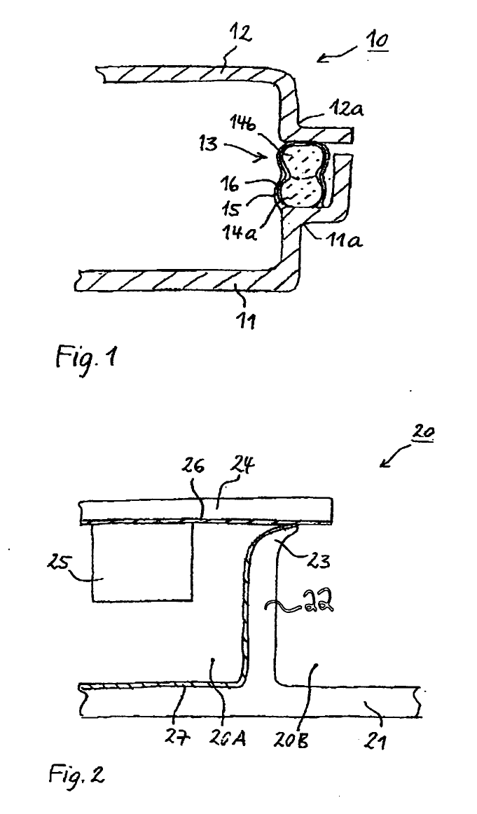

FIG. 1 is a diagrammatic cross-sectional drawing of a device housing according to a first embodiment of the invention and

FIG. 2 is a diagrammatic cross-sectional drawing of a device housing according to a second embodiment of the invention.

FIG. 1 shows part of a device housing 10 made of metal, e.g. deep-drawn Al sheet, comprising a lower housing shell 11 and an upper housing shell 12, which are connected to one another by fixation means not shown in the drawing (for example, screws or a catch fastener). Near the edge of the housing 10, where the lower and upper housing shells 11, 12 each have an outwardly bent region 11a or 12a, a shielding element in the form of an outer housing gasket 13 is inserted between the shells.

The outer housing gasket 13 is composed of two elastomer beads 14a, 14b dispensed onto the outwardly bent region 11a of the lower housing shell 11. Of these two beads, the lower one 14a adheres fixedly to the surface of the lower housing shell 11, while the upper elastomer bead 14b is fused to the lower bead 14a as a result of having been applied immediately after the latter was formed. Onto the base gasket profile 14a/14b thus formed two layers have been applied, first a thin copper layer, as a highly conductive basal layer, and then a covering layer 16 made of a tin alloy with low lead content; each layer is applied by a high-vacuum coating method. The thicknesses of the basal layer 15 and covering layer 16 are such as to obtain on one hand the necessary deformability of the outer housing gasket 13, and on the other hand its shielding action; depending on the intended use of the housing 10, resistance to environmental influences (moisture, salt water etc.) should also be taken into account.

FIG. 2 shows a schematic cross section of part of a housing 20 made of a thermoplastic polymer by injection molding; the drawing shows only that part of the housing bottom 21 that includes a vertically upright partition 22. The partition 22 separates a housing region 20A, which is to be shielded from EMI, from a second housing region 20B, so that the two regions are sealed off from one another both mechanically and electromagnetically. On the upper edge of the partition 22, which is tapered in cross section to form a flexible sealing lip 23, lies a circuit board 24 with electronic components, to symbolize which an EMI-sensitive component 25 is shown here.

In the upward direction the first housing region 20A is substantially tightly sealed by a conductive surface coating 26 on the circuit board 24. Downward and toward the side the electromagnetic shielding is ensured by tin-alloy layer 27 that has been applied to the whole surface of the left-hand section of the housing bottom 21 and the adjoining (left) surface of the partition 22.

The implementation of the invention is not restricted to these examples, but is also possible in a large number of further modifications that are within the competency of a person skilled in the art. In particular, in diverse housing designs injection-molded shielding walls, where appropriate formed in such a way that their material is continuous with that of other parts of the housing, can be combined with shielding gaskets applied from a dispenser. Similarly, shielding gaskets or walls coated with a single-component, tin-based thin layer can be combined in one and the same housing with those having a two-component conductive coating comprising a basal layer (Cu, Ag or the like) and a tin covering layer.

List of Reference Numerals

| | |
|---|---|
| 10; 20 | Housing |
| 11; 21 | Lower housing shell |
| 11a | Outward bend |
| 12 | Upper housing shell |
| 12a | Outward bend |
| 13 | Outer housing gasket (shielding gasket) |
| 14a, 14b | Elastomer bead |
| 14a/14b | Basic gasket profile |
| 15 | Thin copper layer (basal layer) |
| 16; 27 | Tin-alloy layer (covering layer) |
| 20A, 20B | Housing region |
| 22 | Partition |
| 23 | sealing lip |
| 24 | Circuit board |
| 25 | Component |
| 26 | Surface coating |

1. Device housing incorporating a shielding gasket or wall with a conductive coating, characterized in that the conductive coating is formed as a thin layer made of tin or a tin alloy.

2. Device housing according to claim 1, characterized in that the tin alloy is a Sn/Pb alloy with low Pb content, in particular less than 5% Pb by mass.

3. Device housing according to claim 1 or 2, characterized in that the conductive coating is constructed in two layers, comprising a basal layer made of a highly conductive metal, in particular copper or a copper alloy, which is covered by a thin layer made of tin or a tin alloy.

4. Device housing according to one of the preceding claims, characterized in that the conductive coating has a total thickness in the range between 0.5 μm and 10 μm.

5. Device housing according to one of the preceding claims, characterized in that the shielding gasket or wall is formed by an elastomer applied to a substrate by means of a dispenser.

6. Device housing according to claim 5, characterized in that the shielding wall is composed of several substantially superimposed beads of the elastomer or a single, tall elastomer bead, the height of which amounts to at least twice its width.

7. Device housing with a shielding gasket or wall having a conductive coating, in particular according to one of the claims 1 to 4, characterized in that the shielding gasket or wall consists substantially of a thermoplastic polymer.

8. Device housing with a shielding gasket or wall having a conductive coating, in particular according to one of the claims 1 to 4, characterized in that the shielding gasket or wall consists substantially of a duroplastic polymer.

9. Device housing according to claim 7 or 8, characterized in that the shielding gasket or wall is injection molded, in particular in such a way that its material is continuous with that of the substrate.

10. Device housing according to one of the preceding claims, characterized in that the material of which the shielding gasket or wall is made includes a conductive filling, in particular comprising conductive metal and/or carbon particles.

11. Device housing according to one of the preceding claims, characterized in that the conductive coating or at least the covering layer is produced by vacuum deposition or as a sputtered layer.

12. Device housing according to one of the claims 1 to 10, characterized in that the conductive coating or at least the covering layer is produced as a sprayed coating.

13. Device with a housing according to one of the preceding claims, characterized by being designed as a telecommunications or data-communication device.
